(19) United States
(12) Patent Application Publication
(10) Pub. No.: US 2008/0079110 A1
(43) Pub. Date: Apr. 3, 2008

(54) SEMICONDUCTOR DEVICE

(75) Inventors: Shuichi KIKUCHI, Gunman (JP); Shigeaki OKAWA, Tochigi (JP); Kiyofumi NAKAYA, Saitama (JP); Shuji TANAKA, Gunma (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD.; Sanyo Semiconductor Co., Ltd.

(21) Appl. No.: 11/862,365

(22) Filed: Sep. 27, 2007

(30) Foreign Application Priority Data
Sep. 28, 2006 (JP) 2006-265384

(51) Int. Cl. H01L 27/08

(52) U.S. Cl. 257/476; 257/E27.051

(57) ABSTRACT

There is a problem that a reverse off-leak current becomes too large in a Schottky barrier diode. A semiconductor device of the present invention includes a P-type first anode diffusion layer formed in an N-type epitaxial layer, a second anode diffusion layer which is formed so as to surround the first anode diffusion layer, and which has an impurity concentration lower than that of the first anode diffusion layer, N-type cathode diffusion layers formed in the epitaxial layer, and a Schottky barrier metal layer formed on the first and second anode diffusion layers.

This application claims priority from Japanese Patent Application Number JP2006-265384, filed Sep. 28, 2006, the content of which is incorporated herein by reference in its entirety.

### BACKGROUND OF THE INVENTION

1. Field of the Invention

The present invention relates to a semiconductor device that protects a circuit element from an overvoltage.

2. Description of the Related Art

In a conventional semiconductor device, an N-type epitaxial layer is formed on an N-type semiconductor substrate. A P-type diffusion layer is overlapped onto an N-type diffusion layer formed on the epitaxial layer. Then, an anode electrode is formed on the P-type diffusion layer, and a cathode electrode is formed on a back surface of the substrate to form a Zener diode using a PN junction of both diffusion layers. A P-type guard region is formed around the P-type diffusion layer and another guard region is formed on its outer side. A Schottky barrier metal layer is formed in such a way to come in contact with the epitaxial layer surrounded by both guard regions. Then, a Schottky barrier diode is formed of a silicide of the Schottky barrier metal layer and the epitaxial layer. In the conventional semiconductor device, the Zener diode and the Schottky barrier diode are connected in parallel to achieve a reduction in a forward voltage (Vf) of a device itself. This technology is described in Japanese Patent Application Publication No. Hei 8 (1996)-107222 (Pages 2 to 4, FIG. 1).

In a conventional semiconductor device, P-type diffusion layers with a high impurity concentration are formed on a surface of an N-type semiconductor region and a P-type diffusion layer with a low impurity concentration is formed between the diffusion layers with a high impurity concentration. An electrode formed on the surface of the N-type semiconductor region makes an ohmic contact with the P-type diffusion layer with a high impurity concentration to form a Schottky barrier between the P-type diffusion layer with a high impurity concentration and the P-type diffusion layer with a low impurity concentration. In a forming region where the P-type diffusion layer with a high impurity concentration is formed, a Zener diode is formed using a PN junction. On the other hand, in a forming region where the P-type diffusion layer with a low impurity concentration is formed, a diode, which includes the Zener diode and a Schottky barrier, is formed. This structure decreases free carriers (holes) to be injected into the N-type semiconductor region from the P-type diffusion layer and reduces free carriers (holes) to be stored in the vicinity of the PN junction region. This results in a reduced reverse recovery current density. This technology is described in Japanese Patent Application Publication No. Hei 9 (1997)-121062 (Pages 5-6, FIG. 2).

In a conventional planar type semiconductor device, an anode electrode is formed on a top surface of a P-type semiconductor region formed in an N-type semiconductor region. A conductive field plate, which is connected to the anode electrode, is formed on a top surface of the N-type semiconductor region. Moreover, an equipotential ring electrode and the conductive field plate formed on a top surface of the N-type semiconductor region are connected to each other by a resistive field plate. Then, a thickness of an insulation film which is positioned at a lower portion of a boundary between the conductive field plate and the resistive field plate is thickened, and a thickness of an insulation film, which is positioned at a lower portion of the resistive field plate on the equipotential ring electrode, is thinned. This structure intensifies an effect of the resistive field plate to reduce a curvature of a depletion layer placed at the lower portion of the boundary between the conductive field plate and the resistive field plate. This achieves an improvement in a breakdown voltage characteristic in a region where an electric field concentration is apt to occur. This technology is described in Japanese Patent Application Publication No. Hei 8 (1996)-130317 (Pages 3 to 6, FIGS. 2 and 4).

As mentioned above, according to the conventional semiconductor device, the Zener diode and the Schottky barrier diode are connected in parallel in one device. This structure makes it possible to achieve a low voltage drive by use of a forward voltage (Vf) characteristic of the Schottky barrier diode. However, in the Schottky barrier diode, an epitaxial layer is used as a channel for a main current. This causes a problem in which a parasitic resistance is high in the epitaxial layer, thereby making it impossible to reduce an ON-resistance value.

Moreover, according to the conventional semiconductor device, in the Zener diode, the P-type guard region is formed at a lower portion of an end portion of an anode electrode formed on a top surface of the epitaxial layer. Likewise, in the Schottky barrier diode, the P-type guard region is formed at a lower portion of an end portion of the Schottky barrier metal layer. This structure protects a region where an electric field concentration is apt to occur using the P-type guard region. However, in a structure in which the P-type guard region is formed on an outermost periphery, when a reverse bias is applied, the curvature of the depletion layer is likely to be changed in the vicinity of the end portion of the anode electrode and that of the Schottky barrier metal layer. Particularly, when the above end portion is placed in the vicinity of a termination region of the depletion layer, the change in the curvature of the depletion layer is increased. As a result, there is a problem in which the electric field concentration is apt to occur in the region where the curvature of the depletion layer is changed, thereby making it difficult to achieve a desired breakdown voltage characteristic.

Furthermore, according to the conventional semiconductor device, at a Zener diode operating time, free carriers (holes) which are minority carriers are excessively stored in the N-type epitaxial layer. Then, when the Zener diode is turned off, it is necessary to remove the stored free carriers (holes) from the P-type diffusion layer. At this time, a concentration of the free carriers (holes) in the vicinity of the P-type diffusion layer is high, thereby leading to an increase in an absolute value of a rate of a change of a reverse recovery current in time (di/dt). Accordingly, there is a problem in which a destruction of a protection diode is caused by the rate of change of the reverse recovery current in time (di/dt).

Still moreover, according to the conventional semiconductor device, the Zener diode and the Schottky barrier diode are connected in parallel to achieve the low voltage drive. However, when the above diode is used as a protection diode for a circuit element that forms a high frequency circuit, there is a problem in which a parasitic capacitance of the Zener diode is increased to cause deterioration in a high frequency characteristic.

Furthermore, the low forward voltage (Vf) characteristic of the Schottky barrier diode is used to allow the protection diode to operate before the circuit element operates when the overvoltage is applied to the circuit element, thereby preventing the circuit element from being destroyed. In such a case, there is a problem that the forward voltage (Vf) characteristic of the Schottky barrier diode is made too low, for example due to the influence of the configuration of the Schottky barrier metal layer formed on the surface of the epitaxial layer or due to other reasons, thereby causing an increase in a reverse off-leak current.

### SUMMARY OF THE INVENTION

The present invention provides a semiconductor device that includes a first anode diffusion layer of opposite conductivity type formed on a semiconductor layer of one conductivity type, a second anode diffusion layer which is formed so as to surround the first anode diffusion layer, and which has an impurity concentration lower than that of the first anode diffusion layer, a cathode diffusion layer of one conductivity type formed in the semiconductor layer, and a Schottky barrier metal layer formed on the first and second anode diffusion layers.

Furthermore, in the semiconductor device of the present invention, the cathode diffusion layer is formed of two diffusion layers of one conductivity type having different impurity concentrations, and is connected to a cathode electrode.

Furthermore, in the semiconductor device of the present invention, the first anode diffusion layer is diffused deeper than the second anode diffusion layer.

Furthermore, in the semiconductor device of the present invention, an electric field shielding film having an electric potential equal to that of the cathode diffusion layer is formed on the semiconductor layer, and the electric field shielding film is placed in a region where a wiring layer to which an anode potential is applied traverses over the cathode diffusion layer.

### BRIEF DESCRIPTION OF THE DRAWINGS

FIGS. 1A and 1B are cross-sectional views each explaining a protection diode according to a preferred embodiment of the present invention.

FIGS. 2A and 2B are cross-sectional views each explaining a PN diode according to the preferred embodiment of the present invention.

FIG. 3 is a view explaining a forward voltage (Vf) of each of the protection diode and a PN diode according to the preferred embodiment of the present invention.

FIG. 4 is a view explaining a circuit into which the protection diode is incorporated according to the preferred embodiment of the present invention.

FIG. 5 is a view explaining a parasitic capacitance of each of the protection diode and the PN diode according to the preferred embodiment of the present invention.

FIG. 6A is a view explaining an electric potential distribution of the protection diode in a reverse bias state according to the preferred embodiment of the present invention, and FIG. 6B is a view explaining an impact ionization occurring region in the protection diode according to the preferred embodiment of the present invention.

FIG. 7 is a view explaining a concentration profile of free carriers (holes) of each of the protection diode and the PN diode according to the preferred embodiment of the present invention.

FIG. 8 is a plane view explaining the protection diode according to the preferred embodiment of the present invention.

FIGS. 9A and 9B are cross-sectional views explaining a protection diode according to another preferred embodiment of the present invention.

FIGS. 10A and 10B are cross-sectional views explaining a PN diode according to another preferred embodiment of the present invention.

FIG. 11A is a view explaining an electric potential distribution of the protection diode in a reverse bias state according to another preferred embodiment of the present invention, and FIG. 11B is a view explaining an impact ionization occurring region in the protection diode according to the another preferred embodiment of the present invention.

### DETAILED DESCRIPTION OF THE PREFERRED EMBODIMENT

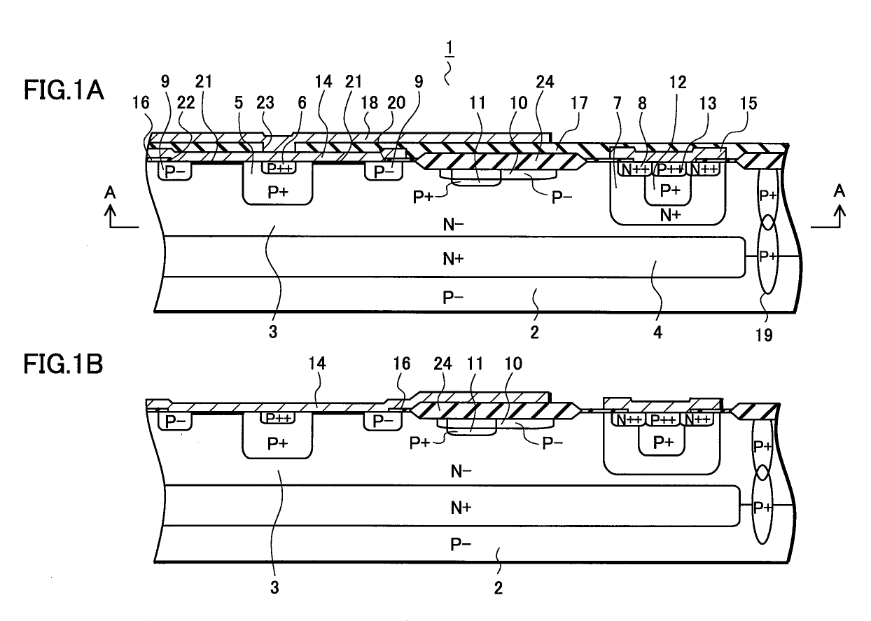

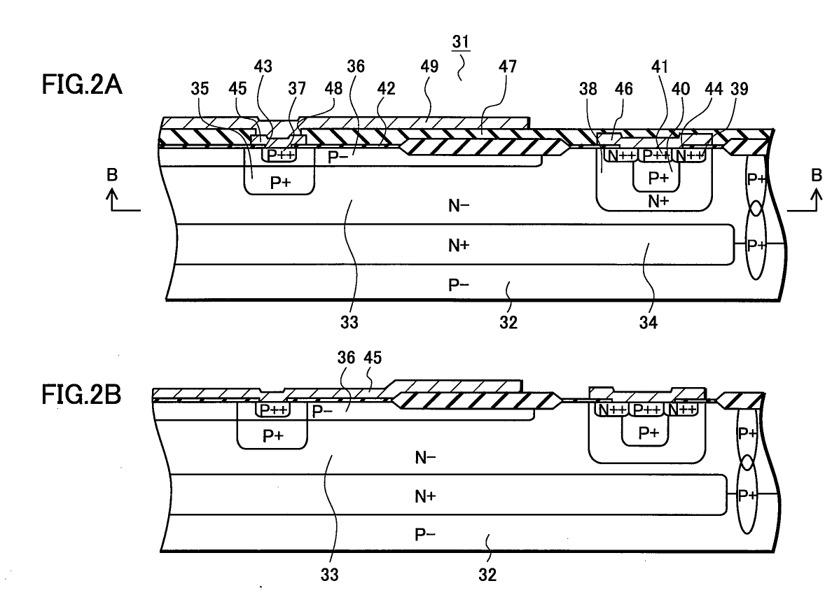

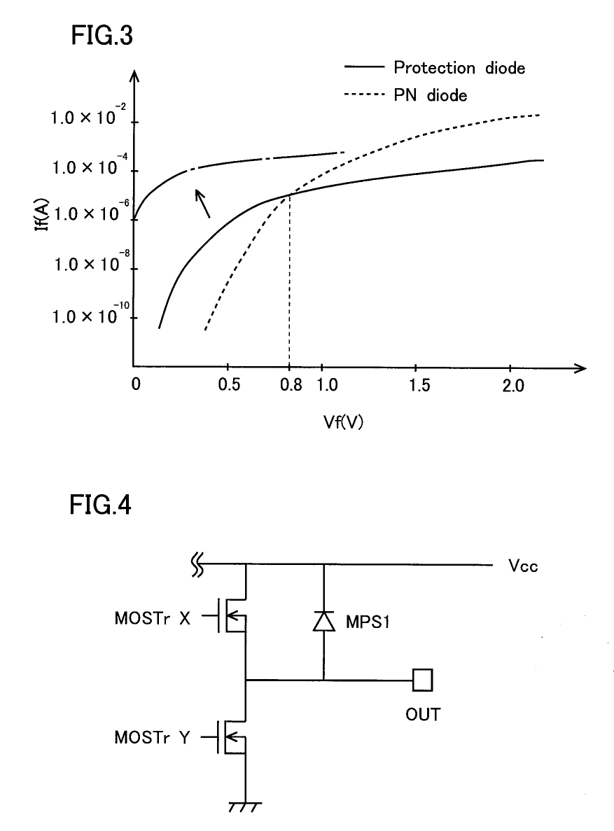

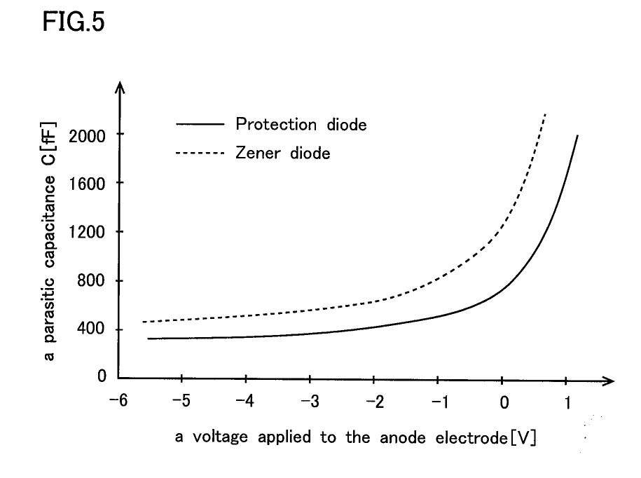

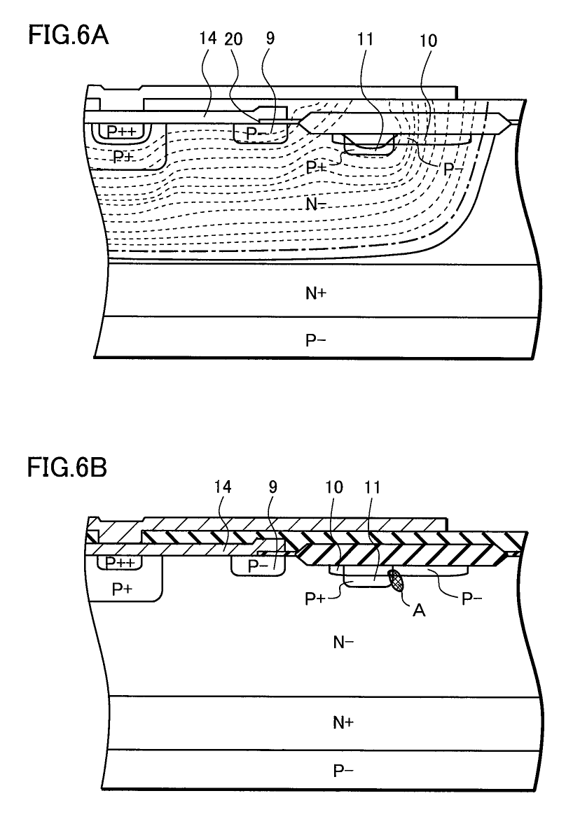

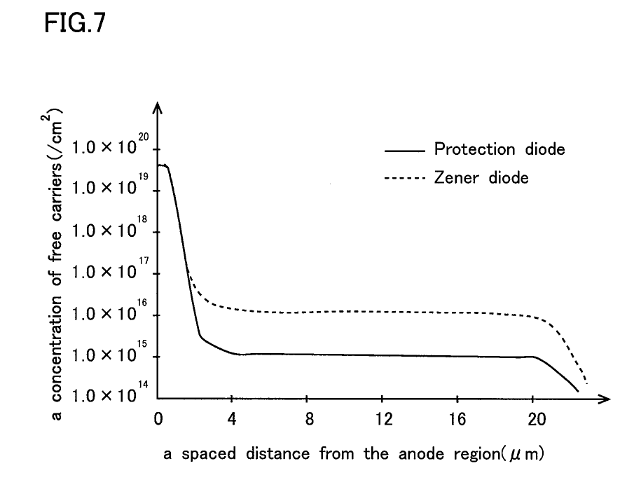

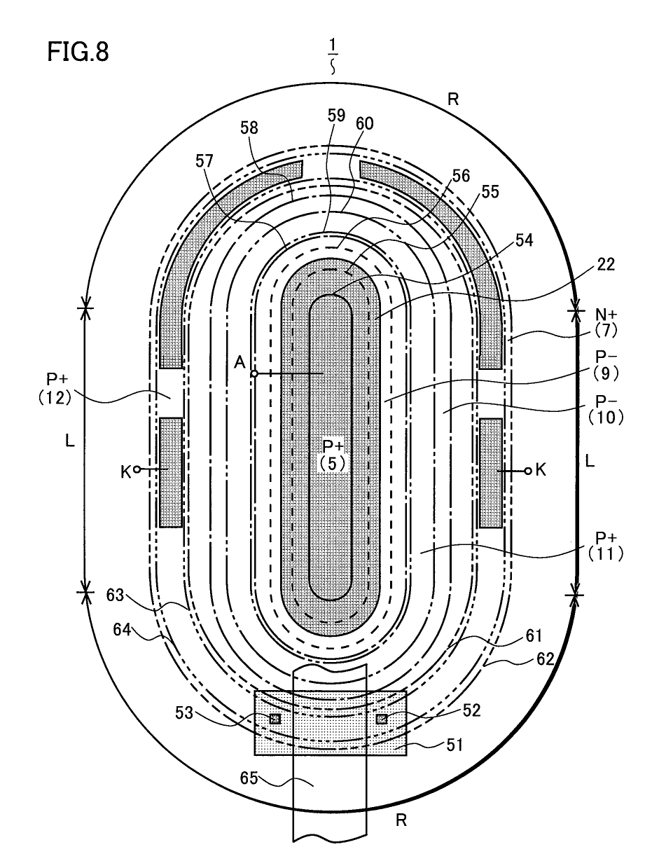

The following will specifically explain a semiconductor device according to one preferred embodiment of the present invention with reference to FIGS. 1 to 7. FIG. 1A and FIG. 1B are cross-sectional views each explaining a protection diode according to one embodiment of the present invention. FIG. 2A and FIG. 2B are cross-sectional views each explaining a PN diode according to the embodiment of the present invention. FIG. 3 is a view explaining a forward voltage (Vf) of each of the protection diode and a PN diode according to the embodiment of the present invention. FIG. 4 is a view explaining a circuit into which the protection diode is incorporated according to the embodiment of the present invention. FIG. 5 is a view explaining a parasitic capacitance value of each of the protection diode and the PN diode according to the embodiment of the present invention. FIG. 6A is a view explaining an electric potential distribution of the protection diode in a reverse bias state according to the embodiment of the present invention. FIG. 6B is a view explaining an impact ionization occurring region in the protection diode according to the embodiment of the present invention. FIG. 7 is a view explaining a concentration profile of free carriers (holes) of each of the protection diode and the PN diode according to the embodiment of the present invention. FIG. 8 is a plane view explaining the protection diode according to the embodiment of the present invention.

As illustrated in FIG. 1A, a protection diode 2 in which a PN diode and a Schottky barrier diode are arranged in parallel mainly includes a P-type monocrystalline silicon substrate 2, an N-type epitaxial layer 3, an N-type buried diffusion layer 4, P-type diffusion layers 5 and 6 serving as an anode region, N-type diffusion layers 7 and 8 serving as a cathode region, P-type diffusion layers 9, 10, 11, 12, and 13, a Schottky barrier metal layer 14 serving as an anode electrode, a metal layer 15 serving as a cathode electrode, insulation layers 16 and 17, and a metal layer 18 connected to the anode electrode. It is noted that conductivity types such as N⁺, N and N⁻ belong in one general conductivity type and conductivity types such as P⁺, P and P⁻ belong in another general conductivity type.

The N-type epitaxial layer 3 is deposited on a top surface of the P-type monocrystalline silicon substrate 2. It is noted that the epitaxial layer 3 of the present embodiment corresponds to “a semiconductor layer” of the present invention. Then, although the present embodiment shows a case in which one epitaxial layer 3 is formed on the substrate 2, the embodiment of the present invention is not limited to this case. For example, as “the semiconductor layer” of the present invention, a plurality of epitaxial layers may be formed on the top surface of the substrate. Moreover, only the substrate may be used as “the semiconductor layer” of the present invention, and the substrate may include an N-type monocrystalline silicon substrate and a compound semiconductor substrate.

The N-type buried diffusion layer 4 is formed in both regions of the substrate 2 and the epitaxial layer 3. As illustrated in FIG. 1, the N-type buried diffusion layer 4 is formed across a forming region of the protection diode 1 divided by an isolation region 19.

The P-type diffusion layers 5 and 6 are formed in the epitaxial layer 3. The P-type diffusion layer 5 is formed on diffusion conditions that, for example, an impurity concentration of a surface thereof is about 10×10¹⁶ to 1.0×10¹⁷ (/cm²) and a diffusion depth is about 5 to 6 (μm). The P-type diffusion layer 6 is formed on diffusion conditions that, for example, an impurity concentration of a surface thereof is about 10×10¹⁹ to 10×10²⁰ (/cm²) and a diffusion depth is about 1 to 3 (μm). Then, the P-type diffusion layer 5 and the N-type epitaxial layer 3 form a PN junction and the P-type diffusion layers 5 and 6 are used as the anode region of a PN diode. It is noted that this embodiment has the P-type diffusion layers 5 and 6. However, only the P-type diffusion layer 5 or P-type diffusion layer 6 may be used. Furthermore, a triple diffusion structure may be used in which a P-type diffusion layer, having, for example, an impurity concentration of a surface thereof which is about 1.0×10¹⁷ to 1.0×10¹⁸ (/cm²) and a diffusion depth of about 2 to 4 (μm), is formed on the P-type diffusion layers 5 and 6.

The N-type diffusion layers 7 and 8 are formed in the epitaxial layer 3 and surround the P-type diffusion layer 5 annularly. The N-type diffusion layers 7 and 8 and the N-type epitaxial layer 3 are used as the cathode region of the PN diode and the Schottky barrier diode. Then, a wide diffusion region is formed as the N-type diffusion layer 7, thereby reducing a parasitic capacitance value. On the other hand, although the N-type diffusion layer 8 is a narrow diffusion layer, this layer is formed to have a high impurity concentration, thereby establishing a low resistance. It is noted that this embodiment has the N-type diffusion layers 7 and 8. However, only one of the N-type diffusion layer 7 and N-type diffusion layer 8 can be used. Also, a multi-diffusion structure such as the triple diffusion structure may be used.

The P-type diffusion layer 9 is formed in the epitaxial layer 3 and surrounds the P-type diffusion layer 5 annularly. The P-type diffusion layer 9 is formed on diffusion conditions that, for example, its surface impurity concentration is about 1.0×10¹⁵ to 1.0×10¹⁶ (/cm²) and a diffusion depth is about 1 to 3(μm). Then, the P-type diffusion layer 9 is formed below an end portion 20 of the Schottky barrier metal layer 14 which serves as an anode electrode. Then, the P-type diffusion layer 9 relaxes an electric field concentration on the end portion 20 of the Schottky barrier metal layer 14 to improve a breakdown voltage characteristic of the protection diode 1. It is noted that this embodiment has the P-type diffusion layer 9. However, the multi-diffusion structure such as the triple diffusion structure may be used instead.

The P-type diffusion layers 10 and 11 are formed to be closer to the N-type diffusion layer 7 than the P-type diffusion layer 9 so that forming regions thereof are overlapped on each other. Also, the P-type diffusion layers 10 and 11 are formed to surround the P-type diffusion layer 5 annularly. The P-type diffusion layer 10 is formed on diffusion conditions that, for example, an impurity concentration of a surface thereof is about 1.0×10¹⁵ to 1.0×10¹⁶ (/cm²) and a diffusion depth is about 1 to 3 (μm). The P-type diffusion layer 11 is formed on diffusion conditions that, for example, its surface impurity concentration is about 1.0×10¹⁷ to 1.0×10¹⁸ (/cm²) and a diffusion depth is about 2 to 4 (μm). Then, the P-type diffusion layers 10 and 11 are formed as floating diffusion layers. Further, although specifically described later, the P-type diffusion layer 11, which has a higher impurity concentration than that of the P type diffusion layer 10, is formed on the P-type diffusion layer 10 to be overlapped thereon. This structure can prevent a region where the P-type diffusion layers 10 and 11 are overlapped from being filled with a depletion layer when a reverse bias is applied to the protection diode 1. As a result, the region where the P-type diffusion layers 10 and 11 are overlapped can keep a capacitive coupling to the metal layer 18 or Schottky barrier metal layer 14. It is noted that the P-type diffusion layers 10 and 11 of the present embodiment are the one in which at least a part of the P-type diffusion layer is not filled with the depletion layer, and design changes may be arbitrarily made to the diffusion structure.

The P-type diffusion layers 12 and 13 are formed in the N-type diffusion layer 7 and their forming regions are overlapped on each other. The P-type diffusion layers 12 and 13 are formed to surround the P-type diffusion layer 5 annularly. The P-type diffusion layer 12 is formed on diffusion conditions that, for example, an impurity concentration of a surface thereof is about 1.0×10¹⁶ to 1.0×10¹⁷ (/cm²) and a diffusion depth is about 5 to 6 (μm). The P-type diffusion layer 13 is formed on diffusion conditions that, for example, its surface impurity concentration is about 1.0×10¹⁹ to 1.0×10²⁰ (/cm²) and a diffusion depth is about 1 to 3 (μm). Then, the metal layer 15, which is used as a cathode electrode, is brought in contact with the N-type diffusion layer 8 and the P-type diffusion layer 13. With this structure, the P-type diffusion layers 12 and 13 are formed to have electric potentials equal to that of as the N-type diffusion layers 7 and 8.

The Schottky barrier metal layer 14 is formed on the top surface of the epitaxial layer 3. The Schottky barrier metal layer 14 is formed, for example, by depositing an aluminum alloy (for example an aluminum silicon (AlSi) layer, an aluminum copper (AlCu) layer or an aluminum silicon copper (AlSiCu) layer) on a titanium (Ti) layer and a titanium nitride (TiN) layer serving as the barrier metal layer. As shown by a thick line, a silicide layer 21 of a titanium silicide (TiSi₂) is formed on the surface of the epitaxial layer 3 positioned between the P-type diffusion layer 5 and the P-type diffusion layer 9. Then, a Schottky barrier diode is formed of the silicide layer 21 of the Schottky barrier metal layer 14, and the epitaxial layer 3. It is noted that metals such as tungsten (W), molybdenum (Mo), tantalum (Ta), cobalt (Co), nickel (Ni), and platinum (Pt) may be used in place of the titanium (Ti) layer. In this case, a tungsten silicide (WSi₂) layer, a molybdenum silicide (MoSi₂) layer, a cobalt silicide (CoSi₂) layer, a nickel silicide (NiSi₂) layer, a platinum silicide (PtSi₂) layer are formed as a silicide layer 21.

The metal layer 15 is formed on the top surface of the epitaxial layer 3. The metal layer 15 has a structure in which the aluminum alloy (for example the aluminum silicon (AlSi) layer, the aluminum copper (AlCu) layer or the aluminum silicon copper (AlSiCu) layer) is layered on the barrier metal layer. Then, the metal layer 15 is used as a cathode electrode and a cathode potential is applied to the N-type diffusion layer 8 and the P-type diffusion layer 13.

The insulation layers 16 and 17 are formed on the upper portion of the epitaxial layer 3. The insulation layers 16 and 17 are formed by selectively layering, for example, a silicon oxide film, a silicon nitride film, a TEOS (Tetra-Ethyl-Orso-Silicate) film, a BPSG (Boron Phospho Silicate Glass) film, an SOG (Spin On Glass) film, and the like. A contact hole 22 is formed in the insulation film 16. The contact hole 22 is filled with the Schottky barrier metal layer 14 and the Schottky barrier metal layer 14 is used as an anode electrode.

The metal layer 18 is formed on a top surface of the insulation layer 17 to cover the region above the forming regions of the P-type diffusion layers 10 and 11. The metal layer 18 has a structure in which the aluminum alloy (for example the aluminum silicon (AlSi) layer, an aluminum copper (AlCu) layer or an aluminum silicon copper (AlSiCu) layer) is layered on the barrier metal layer. A contact hole 23 formed in the insulation layer 17 is filled with the metal layer 18, and the metal layer 18 is connected to the Schottky barrier metal layer 14. With this structure, at least a part of the region where the P-type diffusion layers 10 and 11 are overlapped is capacitively coupled with the metal layer 18 through the insulation layers 16, 17, a field oxide film 23, and the like. Then, a desired electric potential, which is, however, slightly higher than the anode potential, is applied to at least a part of the region where the P-type diffusion layers 10 and 11 are overlapped. At least a part of the region where the P-type diffusion layers 10 and 11 are overlapped and the N-type epitaxial layer 3 are reversely biased to improve the breakdown voltage characteristic of the protection diode 1.

Additionally, in the present embodiment, as illustrated in FIG. 1B, the Schottky barrier metal layer 14 may be formed in such a way to cover the forming regions of the P-type diffusion layers 10 and 11 as in the metal layer 18 illustrated in FIG. 1A. In this case, at least a part of the region where the P-type diffusion layers 10 and 11 are overlapped is capacitively coupled with the Schottky barrier metal layer 14 through the insulation layers 16, a field oxide film 24, and the like. Then, for example, the thickness of, for example, the insulation films 16 and 17 is controlled, then it comes to be possible to apply an electric potential, which is different from the anode potential, to at least a part of the region where the P-type diffusion layers 10 and 11 are overlapped, thereby enabling to control the breakdown voltage characteristic of the protection diode 1.

FIG. 2A illustrates a PN diode 31. It is noted that the PN diode 31 has substantially the same breakdown voltage characteristic as that of the protection diode 1 shown in FIG. 1. The following will explain the structure.

An N-type epitaxial layer 33 is deposited on a top surface of a P-type monocrystalline silicon substrate 32. An N-type buried diffusion layer 34 is formed in both regions of the substrate 32 and the epitaxial layer 33. P-type diffusion layers 35, 36, and 37 are formed in the epitaxial layer 33. The P-type diffusion layers 35, 36 and the N-type epitaxial layer 33 form a PN junction region and the P-type diffusion layers 35, 36 and 37 are used as an anode region of the PN diode.

N-type diffusion layers 38 and 39 are formed in the epitaxial layer 33. The N-type diffusion layers 38 and 39 and the N-type epitaxial layer 33 are used as a cathode region of the PN diode. Then, P-type diffusion layers 40 and 41 are formed in the N-type diffusion layer 38.

An insulation layer 42 is formed on a top surface of the epitaxial layer 33 and contact holes 43 and 44 are formed in the insulation layer 42. A metal layer 45 is connected to the P-type diffusion layer 37 through the contact hole 43 and is used as an anode electrode. A metal layer 46 is connected to the N-type diffusion layer 39 and the P-type diffusion layer 41 through the contact hole 44 and is used as a cathode electrode.

An insulation layer 47 is formed on the insulation layer 42 and a contact hole 48 is formed in the insulation film 47. A metal layer 49 is connected to the metal layer 45 through the contact hole 48. Also, the metal layer 49 is formed to cover a region above a forming region of the P-type diffusion layer 36 and provides a field plate effect.

Additionally, in the present embodiment, as illustrated FIG. 2B, the metal layer 45 may be formed to cover a region above the forming region of the P-type diffusion layer 36 as in the metal layer 49 shown in FIG. 2A.

Next, in FIG. 3, a forward voltage (Vf) of the protection diode 1 is shown by a solid line and a forward voltage (Vf) of the PN diode 31 by a doted line.

As described using FIG. 1, in the protection diode 1, the PN diode and the Schottky barrier diode are arranged in parallel. It is shown from this structure that the forward current (If) of the protection diode 1 is higher than that of the PN diode 31 and has an excellent current capability when Vf is, for example, 0.8 (V) or less. On the other hand, it is shown that the protection diode 1 is driven at a lower electric potential than that of the PN diode 31 when If is, for example, 1.0×10⁻⁸ (A). Namely, with this device characteristic, a MOS transistor connected to an output terminal and the protection diode 1 are connected in parallel, thereby making it possible to protect the MOS transistor from an overvoltage generated when a cathode ray tube is discharged or an load L such as a motor load is turned off.

More specifically, FIG. 4 shows a circuit in which N-channel type MOS transistors X and Y are connected in series between a power supply line (Vcc) and a ground (GND), and a source electrode of the MOS transistor X and a drain electrode of the MOS transistor Y are connected to an output terminal.

The following will explain a case where an overvoltage is applied to an output terminal of a circuit in which the protection diode 1 is not connected between the power supply line (Vcc) and the output terminal. A forward bias is applied by the overvoltage between the source and drain of the MOS transistor X where the reverse bias is applied. At this time, a current more than an allowed value flows between the source and the drain, accordingly, the PN junction region is destroyed and the MOS transistor X is destroyed.

However, in the present embodiment, the protection diode 1 and the MOS transistor X are connected in parallel between the power supply line (Vcc) and the output terminal. In this case, as explained using FIG. 3, when the overvoltage is applied to the output terminal, the protection diode 1 is first operated and almost all current generated by the overvoltage can be let out to the power supply line (Vcc) by the protection diode 1. This results that the current flowing between the source and the drain of the MOS transistor X is reduced, accordingly, it is possible to prevent the PN junction region from being destroyed.

Next, FIG. 5 shows a relationship between a voltage applied to the anode electrode and a parasitic capacitance C (fF). The protection diode 1 is illustrated by a solid line and the PN diode 31 is illustrated by a dotted line.

As described using FIG. 1, in the protection diode 1, the PN diode and the Schottky barrier diode are arranged in parallel. Then, in the protection diode 1, the PN junction region, which is formed in the epitaxial layer 3, is small as compared with that of the PN diode 31. With this structure, when the reverse bias is applied, the parasitic capacitance of the protection diode 1 comes to be smaller than that of the PN diode 31. Then, the reduction in the parasitic capacitance of the protection diode 1 allows a decrease in a leakage of a high frequency signal. For example, when the circuit shown in FIG. 4 is incorporated into an output section of a high frequency circuit, the protection diode 1 can more reduce deterioration in a high frequency characteristic than the PN diode 31.

Next, in FIG. 6A, a thick solid line shows an end region of the depletion layer, a dotted line shows an equipotential line, and a dashed-dotted line shows an equipotential line of 328 (V). The P-type diffusion layers 10 and 11 are floating regions. The region in the overlapping portion between the P-type diffusion layers 10 and 11, indicated by the thick solid line in FIG. 6A, is a high impurity concentration region and thus includes no depletion regions. As such, this region is subject to an electric potential slightly higher than that of the anode potential through capacitive coupling. In other words, this region is capacitively coupled with the metal layer 18.

On the other hand, the end portion 20 of the Schottky barrier metal layer 14 where the electric field concentration is apt to occur is protected by the P-type diffusion layer 9. As mentioned above, the P-type diffusion layer 9 has the low impurity concentration, and the P-type diffusion layer 9 is filled with the depletion layer as illustrated in FIG. 6A. However, the P type diffusion layer 9 is positioned between the P-type diffusion layers 5 and 6 which are not filled with the depletion layer, and the P-type diffusion layers 10 and 11 which are not filled with the depletion layer. With this structure, the distance between the equipotential lines is not reduced below the end portion 20 of the Schottky barrier metal layer 14, accordingly, the electric field concentration is hard to occur. Namely, it is shown that the P-type diffusion layer 9 is protected by the depletion layer which expands from a boundary of the P-type diffusion layers 5, 6 and the epitaxial layer 3, and the depletion layer which expands from a boundary of the P-type diffusion layers 10, 11 and the epitaxial layer 3.

In the P-type diffusion layers 10 and 11, the P-type diffusion layer 10 is extended to the cathode electrode. As mentioned above, the P-type diffusion layer 10 has the low impurity concentration and is filled with the depletion layer as illustrated in FIG. 6A. Then, in the region where the P-type diffusion layer 10 is formed, the distance between the equipotential lines is gradually changed. In other words, the P-type diffusion layer 10, which is filed with the depletion layer, is formed on an outermost periphery from the anode electrode. This structure reduces a change in a curvature of the depletion layer in the termination region thereof, thereby improving the breakdown voltage characteristic of the protection diode 1 as illustrated in FIG. 6A. As a result, it is possible to improve a problem on the deterioration of the breakdown voltage characteristic resulted from forming the Schottky barrier diode, accordingly, the Schottky barrier diode can be driven at a low forward voltage (Vf).

Additionally, as illustrated by a hatched area A in FIG. 6B, an impact ionization occurs in the vicinity of a region where the P-type diffusion layers 10 and 11 cross each other which is placed at the cathode electrode. It is shown in FIG. 6B that the formation of the P-type diffusion layers 10 and 11 prevents the deterioration of the breakdown voltage characteristic at the end portion 20 of the Schottky barrier metal layer 14 where the electric field concentration is apt to occur.

Next, in FIG. 7, a solid line shows a concentration profile of free carriers (holes) of the protection diode 1 at a cross section taken along a line A-A (FIG. 1A) and a dotted line shows a concentration profile of free carriers (holes) of the PN diode 31 at a cross section taken along a line B-B (FIG. 2A). It is noted that a longitudinal axis shows a concentration of free carriers (holes) in the epitaxial layer and a horizontal axis shows a distance away from the anode region. Then, FIG. 7 shows the concentration profiles in a state where Vf=0.8 (V) is applied to the protection diode 1 and the PN diode 31, respectively.

First, as illustrated in FIG. 1, at the time of operating the protection diode 1, the forward voltage (Vf) is applied to the PN junction region of the P-type diffusion layer 5 and the N-type epitaxial layer 3, and the free carriers (holes) are implanted into the epitaxial layer 3 from the P-type diffusion layer 5. On the other hand, as illustrated in FIG. 2, at the time of operating the PN diode 31, the forward voltage (Vf) is applied to the PN junction region of the P-type diffusion layer 34 and the N-type epitaxial layer 33, and the free carriers (holes) are implanted into the epitaxial layer 33 from the P-type diffusion layer 34, similarly. Namely, both the protection diode 1 and the PN diode 31 have substantially the same concentration of the free carriers (holes) in the region close to the P-type diffusion layers 5 and 34.

Next, as illustrated in FIG. 1, in the protection diode 1, the Schottky barrier diode is formed, so that the P-type diffusion layer 9 and the P-type diffusion layers 10 and 11 are formed to be isolated from each other. This structure reduces the PN junction region to which the forward voltage (Vf) is applied and decreases the free carriers (holes) to be implanted into the N-type epitaxial layer 3. As a result, in the protection diode 1, the concentration of free carriers (holes) is reduced in the region isolated from the P-type diffusion layer 5 as compared with the PN diode 31. Additionally, in the epitaxial layer 3, the free carriers (holes) are distributed to cause a conductivity modulation, so that the main current flows with a low ON resistance. Consequently, it is possible to solve the problem of the Schottky barrier diode in which the ON-resistance value is high.

Finally, as illustrated in FIG. 1, the cathode region of the protection diode 1 is formed to have a double diffusion structure of the N-type diffusion layers 7 and 8. With this structure, the free carriers (holes) implanted from the P-type diffusion layer 5 are recombined with free carriers (electrons) implanted from the N-type diffusion layers 7 and 8 in a region close to the N-type diffusion layer 7. At this time, the N-type diffusion layer 7 is widely diffused, thereby making it possible to promote the recombination.

Furthermore, in the protection diode 1, the P-type diffusion layers 12 and 13 to which the cathode potential is applied are formed in the N-type diffusion layer 7. Then, the free carriers (holes) reached the P-type diffusion layers 12 and 13 are discharged from the P-type diffusion layers 12 and 13 to the outside of the epitaxial layer 3 without being recombined. As a result, the concentration of the free carriers (holes) in the region close to the cathode region can be largely reduced and the concentration of the free carriers (holes) in the epitaxial layer 3 can be also reduced. On the other hand, as illustrated in FIG. 2, the cathode region of the PN diode 31 also has the same structure, and the concentration of the free carriers (holes) in the region close to the cathode region is largely reduced.

As mentioned above, in the protection diode 1, the Schottky barrier diode is formed, and the cathode region where the free carriers (holes) are apt to be discharged from the epitaxial layer 3 is formed. This structure can reduces the concentration of the free carriers (holes) stored in the vicinity of the PN junction region of the protection diode 1. As a result, when the protection diode 1 is turned off, an absolute value of a rate of a change of a reverse recovery current in time (di/dt) is reduced, and it is possible to obtain a soft recovery characteristic. This makes it possible to prevent the destruction of the protection diode 1 caused by the rate of the change of the reverse recovery current in time (di/dt).

Next, as illustrated in FIG. 8, the protection diode 1 is formed in, for example, an elliptical shape. In a linear region L of the elliptical shape, the P-type diffusion layer 5 (region surrounded by a solid line), which is used as an anode region, is placed in a central region. Then, in the linear region L and a round region R of the elliptical shape, the P-type diffusion layer 9 (region surrounded by a dotted line) is formed to surround the P-type diffusion layer 5 annularly. As mentioned above, the P-type diffusion layer 9 relaxes the electric field concentration on the end portion 20 (FIG. 1) of the Schottky barrier metal layer 14 (FIG. 1), thereby improving the breakdown voltage characteristic of the protection diode 1.

In the linear region L and the round region R of the elliptical shape, the P-type diffusion layers 10 (region surrounded by a dashed-dotted line) and 11 (region surrounded by a two-dot chain line) are formed to surround the P-type diffusion layer 9 annularly. As mentioned above, the P-type diffusion layers 10 and 11 are used as the floating diffusion layers.

Also, in the linear region L and the round region R of the elliptical shape, the N-type diffusion layers 7 (region surrounded by a three-dot chain line) is formed to surround the P-type diffusion layer 10 annularly. Then, in the region where the N-type diffusion layer 7 is formed, the P-type diffusion layer 12 (region surrounded by a four-dot chain line) is formed in an annular shape and the forming region thereof is overlapped on the N-type diffusion layer 7. Additionally, although not illustrated, on the P-type diffusion region 5, the P-type diffusion layer 6 (FIG. 1) is formed and the forming region thereof is overlapped on the P-type diffusion layer 5. Also, on the N-type diffusion region 7, the N-type diffusion layer 8 (FIG. 1) and the P-type diffusion layer 13 (FIG. 1) are formed and the forming regions thereof are overlapped on the N-type diffusion layer 7.

With this structure, the protection diode 1 can cause a current to flow in the linear region L and the round region R of the elliptical shape, and improve the current capability. Further, in the round region R of the elliptical shape, the round shape and the P-type diffusion layer 9 relax the electric field concentration, thereby making it possible to improve the breakdown voltage characteristic of the protection diode 1. Furthermore, the elliptical shape of the protection diode 1 allows a device size to be reduced.

Still moreover, as illustrated in FIG. 1, the contact hole 22 (FIG. 1) is formed to have an opening from the P-type diffusion layer 5 to a part of the P-type diffusion layer 9. The Schottky barrier metal layer 14 is connected to the P-type diffusion layer 5, the N-type epitaxial layer 3 (FIG. 1), and the P-type diffusion layer 9 through the contact hole 22. As mentioned above, the Schottky barrier metal layer 14 is directly formed on the top surface of the epitaxial layer 3. Then, the Schottky barrier metal layer 14 is formed to keep flatness over the wide region in the contact hole 22. With this structure, the contact hole 23 is formed on the surface directly above the Schottky barrier metal layer 14, through which the metal layer 18 is connected to the Schottky barrier metal layer 14. In other words, the contact hole 23 is formed on the contact hole 22 which is provided for the Schottky barrier metal layer 14. As a result, it is prevented that a wiring is routed to the Schottky barrier metal layer 14, and a wiring pattern area can be reduced. Additionally, in the explanation of FIG. 8, the same reference numerals as those of FIG. 1 are used for the same structural elements as those of FIG. 1, and the reference numerals are parenthesized in FIG. 8. In FIG. 8, the shaded area in the center shows the position of the contact hole for the anode, and the shaded area covering the anode from the sides and the top shows the position of the contact hole for the cathode.

Finally, in the round region R of the elliptical shape, an electric field shielding film 51 is formed in a region which is placed at a lower portion of a wiring layer (not shown) to which an anode potential is applied, the region in which the wiring layer to which at least the anode potential is applied and the N-type cathode diffusion layer 7 cross each other. The electric field shielding film 51 is formed in a process shared with a process for forming a gate electrode of a MOS transistor (not shown) and made of a polysilicon film. Then, through contact holes 52 and 53 formed on an insulation layer between the epitaxial layer 3 and the electric field shielding film 51, the electric field shielding film 51 is connected to the diffusion layers which serves as the cathode region. Namely, an electric potential substantially equal to the cathode potential is applied to the electric field shielding film 51. With this structure, the electric field shielding film 51 has a shield effect to the wiring layer to which the anode potential is applied. Then, the cathode region is reversed by an electric potential difference between the cathode potential and the anode potential, thereby making it possible to prevent the anode region and the isolation region 19 (FIG. 1) from being short-circuited.

It is noted that the case has been explained in which the silicide layer 21 is formed between the P-type diffusion layer 5 serving as the anode region, and the P type diffusion layer 9 serving as the anode region. According to this structure, the P-type diffusion layer 5 is diffused deeper than the P-type diffusion layer 9, so that a bottom surface of the P-type diffusion layer 5 is largely separated away in a vertical direction from the surface of the epitaxial layer 3. Then, the depletion layer expanding from the boundary of the P-type diffusion layer 5 and the epitaxial layer 3, expands to a wide region in a horizontal direction. As a result, the spaced distance between the P-type diffusion layer 5 and the P-type diffusion layer 9 can be increased, thereby making it possible to expand the forming region of the silicide layer 21. This allows an improvement of the current capability of the Schottky diode without increasing the P-type diffusion layer connected to the anode electrode. Moreover, by suppressing an increase of the PN junction region, an increase of the parasitic capacitance and deterioration in the high frequency characteristic can be prevented. However, the present embodiment is not limited to this structure. In order to improve the forward voltage (Vf) characteristic of the Schottky barrier diode in the protection diode, the space between the P-type diffusion layer 5 and the P-type diffusion layer 9 is increased, and the silicide layer 21 is formed over a wide region. New P-type diffusion layers to which the anode potential is applied may be arranged between the P-type diffusion layer 5 and the P-type diffusion layer 9 at substantially constant intervals. In this case, by forming a plurality of multiple P-type diffusion layers, it is possible to reduce the change in the curvature of the depletion layer in the forming region of the silicide layer 21, and to retain the breakdown voltage characteristic of the protection diode. In addition, various modifications can be made without departing from the scope of the embodiment of the invention.

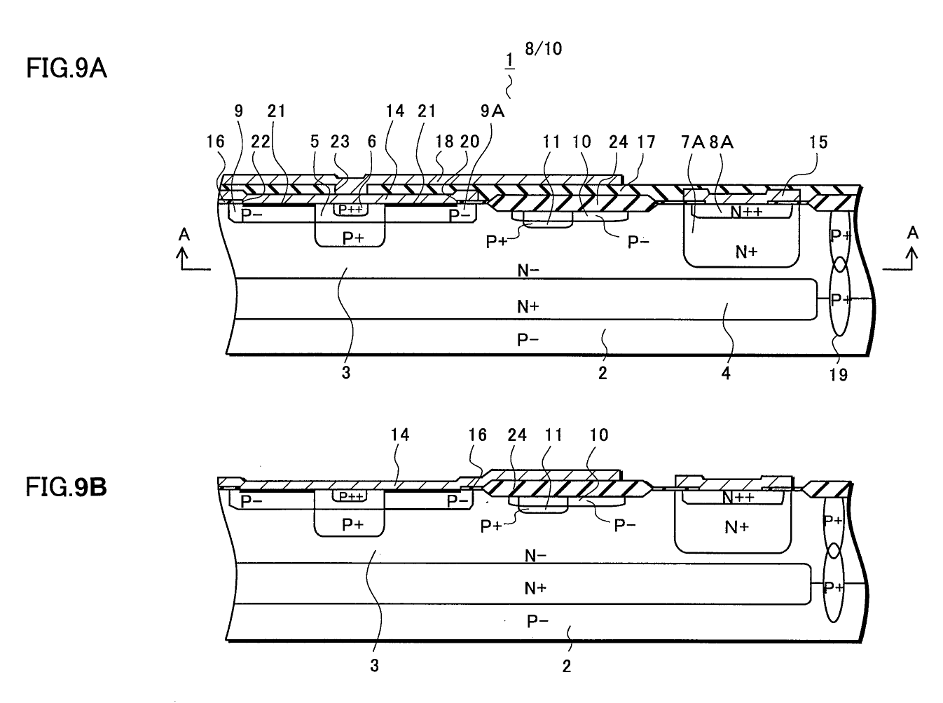

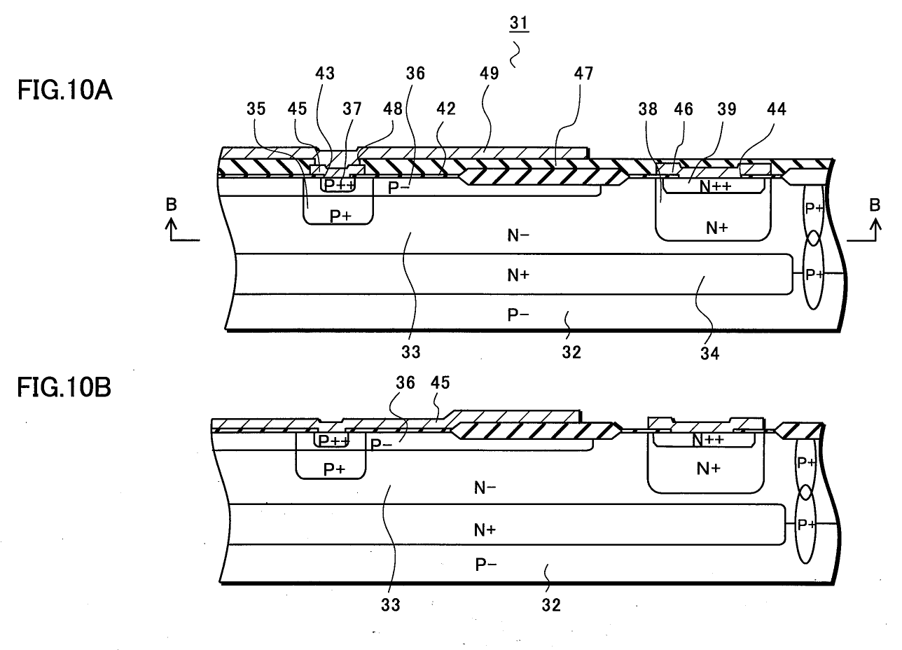

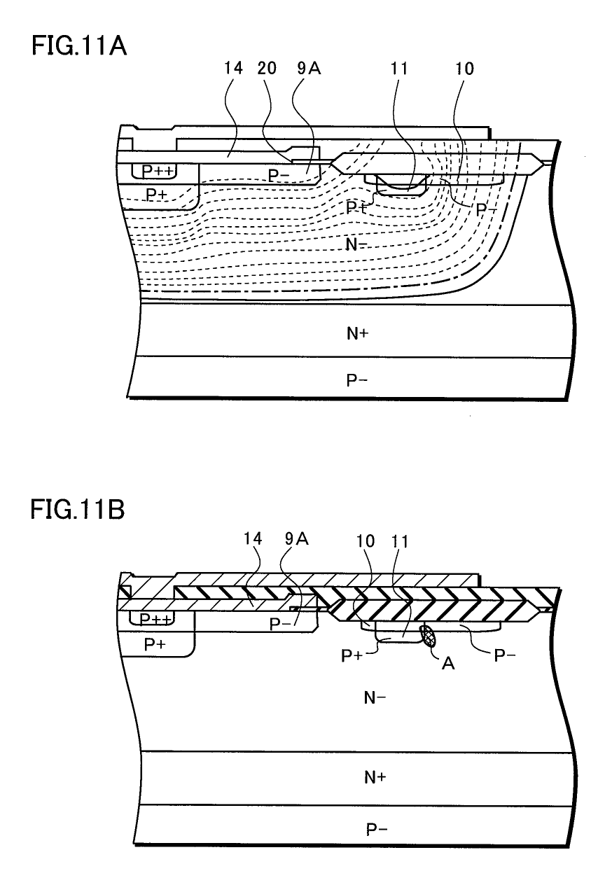

Next, with reference to FIGS. 9 to 11, another embodiment of the present invention will be described. Note that, in order to avoid redundant description, the same constituent components as those in the above embodiment will be denoted by the same reference numerals and description thereof will be omitted.

Here, the semiconductor device of the embodiment and a semiconductor device of the another embodiment are different from each other in the configuration of the P-type diffusion layer 9A on the anode side and in the configurations of the N-type diffusion layers 7A and 8A on the cathode side.

Specifically, in the semiconductor device of the embodiment, the P-type diffusion layer 9 (FIG. 1) is formed at a position spaced apart from the P-type diffusion layer 5. Thus, the low forward voltage (Vf) characteristic of the Schottky barrier diode is used to allow the protection diode to operate before the circuit element operates when the overvoltage is applied to the circuit element, thereby preventing the circuit element from being destroyed. However, there is a case where the forward voltage (Vf) characteristic of the Schottky barrier diode is made too low, for example, under the influence of the configuration of the Schottky barrier metal layer 14 formed on the surface of the epitaxial layer 3, and the like, thereby causing an increase in the reverse off-leak current.

This means a case where, in the characteristic diagram shown in FIG. 3, for example, the solid curve representing the protection diode is moved in the arrow direction and the forward voltage (Vf) characteristic is lowered as indicated by the dashed line, thereby causing an increase in the reverse off-leak current.

In such a case, by forming a P-type diffusion layer 9A so as to surround the P-type diffusion layer 5 as shown in FIGS. 9A and 9B, the forward voltage (Vf) characteristic can be prevented from becoming too low. Thus, a problem that the reverse off-leak current becomes too large is solved.

Moreover, as to the N-type diffusion layers 7 and 8 (FIG. 1) on the cathode side, the P-type diffusion layers 12 and 13 (FIG. 1) are provided in the N-type diffusion layer 7 (FIG. 1). However, in order to improve the breakdown voltage in the high-temperature operation, the configurations of the P-type diffusion layers 12 and 13 (FIG. 1) are omitted.

Specifically, although there is no problem in the operation at room temperature, it is possible to avoid a risk that the presence of the P-type diffusion layers 12 and 13 (FIG. 1) may induce destruction by causing a BiP operation in this region in the case of the operation at a high temperature (for example, 100 to 150° C.).

According to the present invention, the low forward voltage (Vf) characteristic of the Schottky barrier diode is used to allow the protection diode to operate before the circuit element operates when the overvoltage is applied to the circuit element, thereby making it possible to prevent the circuit element from being destroyed.

The second anode diffusion layer having the impurity concentration lower than that of the first anode diffusion layer of opposite conductivity type formed in the semiconductor layer of one conductivity type is formed so as to surround the first anode diffusion layer. Thus, the forward voltage (Vf) characteristic of the Schottky barrier diode is prevented from becoming too low, thereby preventing the reverse off-leak current from becoming too large.

Moreover, the cathode diffusion layer is formed of the two diffusion layers of one conductivity type having different impurity concentrations. Thus, a higher withstand voltage can be achieved.

What is claimed is:

1. A semiconductor device comprising:
a semiconductor layer of a first general conductivity type;
a first anode diffusion layer of a second general conductivity type formed in the semiconductor layer;
a second anode diffusion layer of the second general conductivity type formed in the semiconductor layer so that the first anode diffusion layer is confined within a lateral area of the second anode diffusion layer and an impurity concentration of the second anode diffusion layer is lower than an impurity concentration of the first anode diffusion layer;
a cathode diffusion layer of the first general conductivity type formed in the semiconductor layer; and
a Schottky barrier metal layer disposed on the first and second anode diffusion layers.

2. The semiconductor of claim 1, wherein the cathode diffusion layer comprises two diffusion layers of the first general conductivity type having different impurity concentrations and is connected to a cathode electrode.

3. The semiconductor device of claim 1, wherein the first anode diffusion layer is deeper in the semiconductor layer than the second anode diffusion layer.

4. The semiconductor device of claim 2, wherein the first anode diffusion layer is deeper in the semiconductor layer than the second anode diffusion layer.

5. The semiconductor device of claim 1, further comprising an electric field shielding film formed on the semiconductor layer and a wiring layer to which an anode potential is applied, wherein the electric filed shielding film is configured to receive the same electric potential as applied to the cathode diffusion layer and placed where the wiring layer intersects the cathode diffusion layer.

6. The semiconductor device of claim 2, further comprising an electric field shielding film formed on the semiconductor layer and a wiring layer to which an anode potential is applied, wherein the electric filed shielding film is configured to receive the same electric potential as applied to the cathode diffusion layer and placed where the wiring layer intersects the cathode diffusion layer.

7. The semiconductor device of claim 3, further comprising an electric field shielding film formed on the semiconductor layer and a wiring layer to which an anode potential is applied, wherein the electric filed shielding film is configured to receive the same electric potential as applied to the cathode diffusion layer and placed where the wiring layer intersects the cathode diffusion layer.

8. The semiconductor device of claim 4, further comprising an electric field shielding film formed on the semiconductor layer and a wiring layer to which an anode potential is applied, wherein the electric filed shielding film is configured to receive the same electric potential as applied to the cathode diffusion layer and placed where the wiring layer intersects the cathode diffusion layer.

9. The semiconductor device of claim 1, wherein the cathode diffusion layer surrounds the first and second diffusion layers.

10. The semiconductor device of claim 1, further comprising a floating diffusion layer of the second general conductivity type formed in the semiconductor layer so as to be disposed between the second anode diffusion layer and the cathode diffusion layer.
